(19) United States
(12) Patent Application Publication
(10) Pub. No.: US 2025/0320319 A1
(43) Pub. Date: Oct. 16, 2025

(54) PHOTOCURABLE COMPOSITION COMPRISING ANTI-BLOCKING AGENT

(71) Applicant: Canon Kabushiki Kaisha, Tokyo (JP)

(72) Inventors: Fen WAN, Austin, TX (US); Caroline M. MCCUISTION, Austin, TX (US); Weijun LIU, Cedar Park, TX (US)

(21) Appl. No.: 18/631,129

(22) Filed: Apr. 10, 2024

(51) Int. Cl. C08F 12/32; B05D 5/08

(52) U.S. Cl. CPC C08F 12/32; B05D 5/08; B05D 2203/30

(57) ABSTRACT

A photocurable composition can comprise a polymerizable material, an anti-blocking agent, and a photoinitiator, wherein the polymerizable material can consist essentially of at least one multi-functional aromatic vinyl monomer; the anti-blocking agent may have a structure of formula (1) or formula (2):

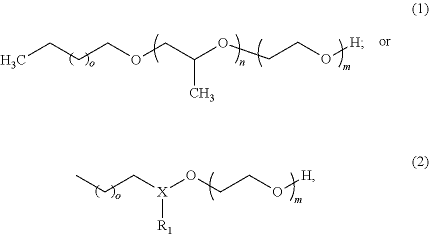

wherein m is 8-15, n is 7-15, o is 8-20; X is aryl or CH₂, and R₁ is H or C₁-C₁₀-alkyl; and a viscosity of the photocurable composition is not greater than 50 mPa·s at 23° C. The photocurable composition can have a low contact angle to a silicon substrate of not greater than 25 degrees; and a low release force may be required to remove a superstrate after subjecting the photocurable composition to photo-curing.

### FIELD OF THE DISCLOSURE

The present disclosure relates to a photocurable composition, particularly to a photocurable composition adapted for inkjet adaptive planarization.

### BACKGROUND

Inkjet Adaptive Planarization (IAP) is a process which planarizes a surface of a substrate, e.g., a wafer containing an electronic circuit, by jetting liquid drops of a curable composition on the surface of the substrate and bringing a flat superstrate in direct contact with the added liquid to form a flat liquid layer. The flat liquid layer is typically solidified under UV light exposure, and after removal of the superstrate a planar surface is obtained which can be subjected to subsequent processing steps, for example baking, etching, and/or further deposition steps.

Integrated circuit fabrication often involves hundreds of sequential process steps, of which IAP is a very critical and multiple used step. The curable composition used for IAP, often also called “IAP resist,” needs to comply with a large property-profile, such as low viscosity (required by inkjet dispensing and filling the gaps), being free of impurities and particles, low evaporation to avoid material loss, a fast-curing speed, low separation force during removal of the superstrate after curing, and good mechanical strength and high etch resistance of the photo-cured layers. It is further of high importance that the cured IAP resist has a high thermal stability and low shrinkage if exposed to high temperatures, because downstream processing often involves temperatures in the range of 350° C. up to 450° C.

There exists a need for improved IAP materials leading to planar cured layers with high thermal stability.

### SUMMARY

In one embodiment, a photocurable composition can comprise a polymerizable material, an anti-blocking agent, and a photoinitiator, wherein the polymerizable material consists essentially of at least one multi-functional aromatic vinyl monomer; and the anti-blocking agent can have a structure of formula (1) or formula (2):

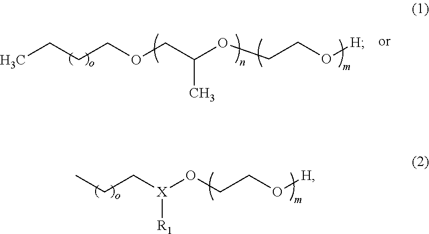

wherein m is 8-15, n is 7-15, o is 8-20; X is aryl or CH₂, and R₁ is H or C₁-C₁₀-alkyl; and wherein a viscosity of the photocurable composition may be not greater than 50 mPa·s at 23° C.

In one aspect of the photocurable composition, the amount of the anti-blocking agent can be at least 0.2 wt % and not greater than 5 wt % based on the total weight of the photocurable composition.

In a further aspect of the anti-blocking agent of the photocurable composition can comprise a surface tension of at least 28 mN/m and not greater than 37 mN/m.

In a particular aspect, the anti-blocking agent can have the structure of formula (1):

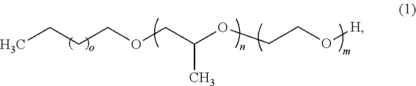

wherein m is 9-15, n is 7-12, and o is 13-20

In another embodiment of the photocurable composition, the at least one multi-functional aromatic vinyl monomer can include a divinylbiphenyl monomer (DVBPh), or a trivinylbiphenyl monomer (TVBPh), or a trivinylphenyl monomer (TVPh), or a combination thereof.

In a particular aspect, the multi-functional aromatic vinyl monomer of the polymerizable material can be selected from:

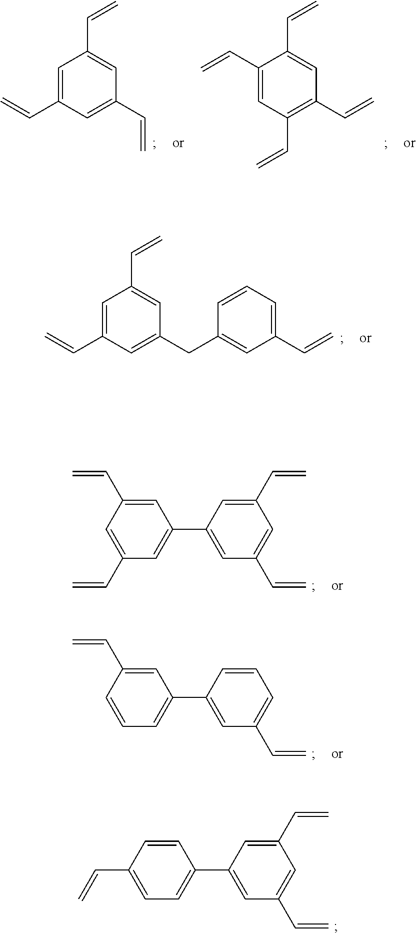

or any combination thereof.

In a certain particular aspect, the multi-functional aromatic vinyl monomer includes

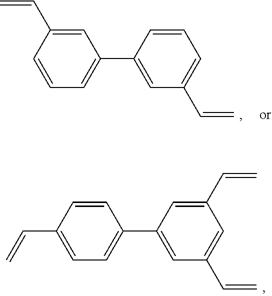

or a combination thereof.

In one embodiment of the photocurable composition, the amount of the polymerizable material can be at least 90 wt % based on the total weight of the photocurable composition.

In another aspect of the photocurable composition, the carbon content of the polymerizable material can be at least 90 percent based on the total weight of the polymerizable material.

In a further aspect, the photocurable composition can be essentially free of a solvent.

In another aspect, the photocurable composition can be essentially free of a fluorine-containing surfactant.

In yet a further aspect, the contact angle of the photocurable composition towards a surface of a silicon substrate may be not greater than 25°.

In one aspect, a release force reduction of the photocurable composition can be at least 50%.

In another embodiment, a laminate can comprise a substrate and a photo-cured layer overlying the substrate, wherein the photo-cured layer may be formed from the above-described photocurable composition.

In one aspect of the laminate, the photo-cured layer can have an initial degradation temperature T(X) of at least 350° C.

In one embodiment, a method of forming a photo-cured layer on a substrate can comprise: applying a layer of a photocurable composition on the substrate, wherein the photocurable composition comprises a polymerizable material, an anti-blocking agent, and a photoinitiator, wherein the polymerizable material consists essentially of at least one multi-functional aromatic vinyl monomer; the anti-blocking agent may have structure of formula (1) or formula (2):

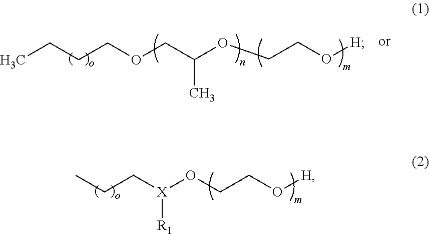

wherein m is 8-15, n is 7-15, and o is 8-20; X is benzol or CH₂, and R₁ is H or C₁-C₁₀-alkyl, and a viscosity of the photocurable composition is not greater than 50 mPa·s at 23° C.; bringing the photocurable composition into contact with a superstrate or an imprint template; irradiating the photocurable composition with light to form a photo-cured layer; and removing the superstrate or the imprint template from the photo-cured layer.

In one aspect of the method, a release force reduction of the photocurable composition can be at least 50%.

In another aspect of the method, the at least one multi-functional aromatic vinyl monomer can include a divinylbiphenyl monomer (DVBPh), or a trivinylbiphenyl monomer (TVBPh), or a trivinylphenyl monomer (TVPh), or a combination thereof.

In a certain aspect of the method, the initial degradation temperature T(X) of the photo-cured layer can be at least 350° C.

In another embodiment, a method of manufacturing an article can comprise: applying a layer of a photocurable composition on a substrate, wherein the photocurable composition comprises a polymerizable material, an anti-blocking agent, and a photoinitiator, wherein the polymerizable material consists essentially of at least one multi-functional aromatic vinyl monomer; the anti-blocking agent has a structure of formula (1) or formula (2):

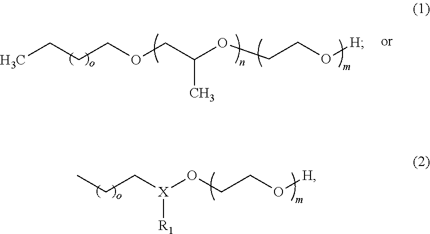

wherein m is 8-15, n is 7-15, and o is 8-20; X is benzol or CH₂, and R₁ is H or C₁-C₁₀-alkyl, and a viscosity of the photocurable composition is not greater than 50 mPa·s at 23° C.; bringing the photocurable composition into contact with a template or a superstrate; irradiating the photocurable composition with light to form a photo-cured layer; removing the template or the superstrate from the photo-cured layer; forming a pattern on the substrate; processing the substrate on which the pattern has been formed in the forming; and manufacturing an article from the substrate processed in the processing.

### DETAILED DESCRIPTION

The following description is provided to assist in understanding the teachings disclosed herein and will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

The present disclosure is directed to a photocurable composition comprising a polymerizable material, an anti-blocking agent, and a photoinitiator, wherein the polymerizable material can consist essentially of at least one multi-functional aromatic vinyl monomer and the anti-blocking agent may have a structure of formula (1) or formula (2):

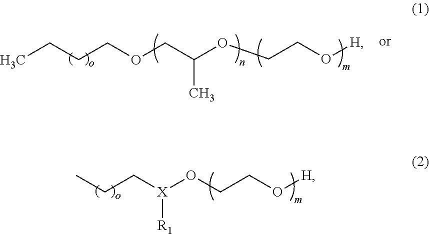

wherein m is 8-15, n is 7-15, and o is 8-20, X is aryl or CH₂, and R₁ is H or C₁-C₁₀ alkyl.

In a particular aspect, the anti-blocking agent can have the above structure of formula (1), wherein m is 9-15, n is 7-12, and o is 13-20.

The photocurable composition of the present disclosure can have the advantage of being usable in inkjet adaptive planarization (IAP) processing by having a low viscosity, a high thermal stability after curing, high etch resistance, and low shrinkage if exposed to high temperatures. A further advantage is a low release force needed to remove the superstrate after photo-curing.

In one aspect, the amount of the anti-blocking agent can be at least 0.2 wt % based on the total weight of the photocurable composition, or at least 0.5 wt %, or at least 1 wt %, or at least 1.5 wt %, or at least 2.0 wt %, or at least 2.5 wt %. In another aspect, the amount of the anti-blocking agent may be not greater than 5.0 wt %, or not greater than 4.0 wt %, or not greater than 3.0 wt %, or not greater than 2.0 wt %.

In a further aspect, the anti-blocking agent can have a surface tension of at least 28 mN/m, or at least 30 mN/m, or at least 31 mN/m. In another aspect, the surface tension of the anti-blocking agent may be not greater than 40 mN/com, or not greater than 37 mN/m, or not greater than 35 mN/m, or not greater than 33 mN/m, or not greater than 32.5 mN/m.

In one embodiment, the anti-blocking agent can have a molecular weight of not greater than 2500 g/ml, or nor greater than 2200 g/mol, of not greater than 2000 g/mol, or not greater than 1500 g/mol, or not greater than 1000 g/mol. In another embodiment, the molecular weight of the anti-blocking agent can be at least 400 g/mol, or at least 600 g/mol, or at least 700 g/mol, or at least 800 g/mol, or at least 900 g/mol, or at least 1000 g/mol, or at least 1500 g/mol.

The polymerizable monomers of the photocurable compositions of the present disclosure can have a highly non-polar character. In one embodiment, the polymerizable monomers can comprise only non-polar covalent bonds, wherein the difference in the electronegativity between two atoms forming a covalent bond is not greater than 0.5 (according to the Pauling model). The value of not greater than 0.5 indicates that such polymerizable monomers refer to monomers only containing the elements carbon and hydrogen, but, for example, no oxygen or nitrogen.

In one embodiment, the multi-functional aromatic vinyl monomer of the polymerizable material can comprise one or more benzene rings and at least two vinyl groups directly attached to the one or more benzene rings, and may only comprise the elements carbon and hydrogen. In certain aspects, the multi-functional vinylbenzene monomer can comprise at least two vinyl groups, at least three vinyl groups, or at least four vinyl groups. In a particular aspect, the multi-functional aromatic vinylbenzene monomer can comprise two benzene rings and three vinyl groups attached to the benzene rings. In particular aspects, the multi-functional aromatic vinyl monomer can be a divinylbiphenyl monomer (DVBPh), or a trivinylbiphenyl monomer (TVBPh), or a trivinylphenyl monomer (TVPh), or a combination thereof.

Non-limiting exemplary structures for the multi-functional aromatic vinyl monomer can be:

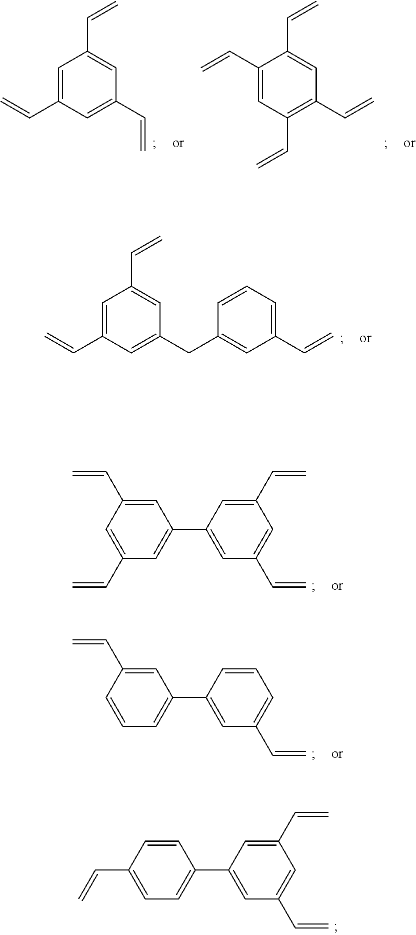

or any combination thereof.

In a certain particular aspect, the multi-functional aromatic vinyl monomer can be 3,3′-divinylbiphenyl (DVBPH); or 3,5,3′-vinyldiphenylmethane (TVPM); or a combination thereof.

As used herein, the phrase “the polymerizable material consisting essentially of at least one multi-functional aromatic vinyl monomer” means that at least 98 wt % of the polymerizable material based on the total weight of the polymerizable material fall under the above-described multi-functional aromatic vinyl monomer, or at least 99 wt %, or at least 99.5 wt %.

The polymerizable material of the photocurable composition can be a major amount of the composition. In one embodiment, the amount of the polymerizable material can be at least 55 wt % based on the total weight of the photocurable composition, or at least 60 wt %, or at least 70 wt %, or at least 80 wt %, or at least 90 wt %, or at least 92 wt %, or at least 95 wt %. In another aspect, the amount of the polymerizable material may be not greater than 98 wt %, or not greater than 96 wt %, or not greater than 94 wt %, or not greater than 90 wt %, or not greater than 85 wt %, or not greater than 80 wt % based on the total weight of the photocurable composition.

Because the multi-functional aromatic vinyl monomer of the polymerizable material may only contain the elements carbon and hydrogen, the polymerizable material can have a high carbon content, which is of advantage for the carbon content of the polymerizable material and the photo-cured layer obtained after solidifying the photocurable composition (herein called after curing). In one aspect, the carbon content of the polymerizable material can be at least 90 wt % based on the total weight of the polymerizable material, or at least 91 wt %, or at least 92 wt %. In another aspect, the carbon content of the polymerizable material may be not greater than 94 wt %, or not greater than 93.5 wt %, or not greater than 93.0 wt % based on the total weight of the polymerizable material.

In a certain embodiment, the photocurable composition of the present disclosure can be essentially free of a solvent.

As used herein, if not indicated otherwise, the term solvent relates to a compound which can dissolve or disperse the polymerizable monomers but does not itself polymerize during the photo-curing of the photocurable composition. The term “essentially free of a solvent” means herein an amount of solvent being not greater than 5 wt % based on the total weight of the photocurable composition. In a certain particular aspect, the amount of a solvent can be not greater than 3 wt %, not greater than 2 wt %, not greater than 1 wt %, or the photocurable composition can be free of a solvent, except for unavoidable impurities.

In another aspect, the photocurable composition and the present disclosure can comprise a solvent in an amount higher than 5 wt % based on the total weight of the photocurable composition. In a particular aspect, the amount of solvent can be at least 7 wt % based on the total weight of the photocurable composition, or at least 10 wt %, or at least 15 wt %, at least 20 wt %, or at least 25 wt %. In another aspect, the amount of solvent may be not greater than 40 wt %, or not greater than 30 wt %, or not greater than 20 wt %, or not greater than 15 wt %, or not greater than 10 wt % based on the total weight of the photocurable composition.

In one aspect, the solvent may be a non-polar solvent, for example, toluene, or heptane.

In another aspect, the solvent can have a similar surface tension as the anti-blocking agent and the multi-functional aromatic vinyl monomer. In a particular aspect, the surface tension of the solvent, the multi-functional aromatic vinyl monomer, and of the anti-blocking agent can be in a range of 28 mN/cm to 40 mN/cm.

In one embodiment, the curable composition of the present disclosure can have a low viscosity which may allow the use of these compositions in IAP applications. In one aspect, the viscosity of the curable composition at a temperature of 23° C. can be not greater than 50 mPa·s, such as not greater than 40 mPa·s, or not greater than 30 mPa·s, not greater than 20 mPa·s, not greater than 15 mPa·s, or not greater than 10 mPa·s. In another aspect, the viscosity may be at least 5 mPa·s, or at least 7 mPa·s. As used herein, all viscosity values relate to viscosities measured at a given temperature with the Brookfield method.

In another embodiment, the contact angle of the polymerizable composition to a surface of a silicon substrate may be not greater than 25°, or not greater than 20°, or not greater than 18°, or not greater than 16°, or not greater than 14°. In a further aspect, the contact angle to a silicon substrate may be at least 4°, or at least 6°, or at least 8°.

The low contact angle of the polymerizable material, together with the low viscosity allow a fast spreading of drops placed on a substrate and the filling of voids.

The photocurable composition further can have the advantage of a low adhesion between photo-cured layer and superstrate, such that a low release force is needed to remove the superstrate after the curing. In one aspect, a release force reduction of the photocurable composition can be at least 50%. As used herein, a release force reduction of at least 50% means a reduction of the release force in comparison to the release force required when a respective comparable photocurable composition is used which does not contain an anti-blocking agent and otherwise contains the same composition with the same ingredients. In certain aspects, the release force reduction can be at least 52%, or at least 54%, or at least 56%, or at least 58%, or at least 60%.

In order to initiate the photo-curing of the composition if exposed to light, one or more photoinitiators can be included in the photocurable composition.

In a certain aspect, the curing can be also conducted by a combination of light and heat curing.

In a further aspect, the photocurable composition can contain at least one optional additive. Non-limiting examples of optional additives can be surfactants, dispersants, stabilizer, co-solvents, initiators, inhibitors, dyes, or any combination thereof.

In another aspect, the photocurable composition of the present disclosure can be essentially free of particles, for example pigment particles. As used herein, being essentially free of particles means that the curable composition contains not more than 50 particles per ml having a size of at least 200 nm, or not more than 50 particles per ml having a size of at least 150 nm, or not more than 50 particles per ml having a size of at least 100 nm, or not more than 50 particles per ml having a size of at least 50 nm, or not more than 50 particles having a size of at least 20nm, or not more than 50 particles per ml having a size of at least 10 nm.

In another embodiment, the present disclosure is directed to a laminate comprising a substrate and a photo-cured layer overlying the substrate, wherein the photo-cured layer can be formed from the photocurable composition described above.

In one aspect, the carbon content of the photo-cured layer can be at least 80 wt %, or at least 85 wt %, or at least 88 wt %, or at least 90 wt %. In another aspect, the carbon content can be not greater than 94 wt % based on the total weight of the photo-cured layer, or not greater than wt %, or not greater than 92 wt %, or not greater than 90 wt %.

In a certain aspect, the laminate can further include one or more layers between the substrate and the photo-cured layer, for example an adhesion layer.

The present disclosure is further directed to a method of forming a photo-cured layer. The method can comprise applying the photocurable composition described above on a substrate; bringing the photocurable composition into contact with a template or superstrate; irradiating the photocurable composition with light to form the photo-cured layer; and removing the template or superstrate from the photo-cured layer.

In one aspect, the light irradiation can be conducted with light having a wavelength between 250 nm to 450 nm. In a preferred aspect, the light irradiation may be conducted with light having a wavelength between 310 nm and 400 nm, or from 340 nm to 390 nm.

The photocurable composition can be adapted that a photo-cured layer formed from the photocurable composition may have a high thermal stability. In one aspect, the onset temperature for the thermal degradation of the of the photo-cured layer may be at least 300° C., or at least 330° C., or at least 350° C., or at least 375° C., or at least 400° C. As used herein, the onset temperature for the thermal degradation is also called “initial degradation temperature T(X),” and relates to the temperature in the TGA curve wherein a deflection of the curve from the almost linear plateau is first observed, shortly before the steep degradation decline of the sample.

The substrate and the solidified (photo-cured) layer may be subjected to additional processing to form a desired article, for example, by including an etching process to transfer an image into the substrate that corresponds to the pattern in one or both of the solidified layer and/or patterned layers that are underneath the solidified layer. The substrate can be further subjected to known steps and processes for device (article) fabrication, including, for example, curing, oxidation, layer formation, deposition, doping, planarization, etching, formable material removal, dicing, bonding, and packaging, and the like. In a certain aspect, the substrate may be processed to produce a plurality of articles (devices).

The cured layer may be further used as an interlayer insulating film of a semiconductor device, such as LSI, system LSI, DRAM, SDRAM, RDRAM, or D-RDRAM, or as a resist film used in a semiconductor manufacturing process.

As further demonstrated in the examples, it has been surprisingly found that photocurable compositions including certain combinations of unpolar multi-functional aromatic vinyl monomers and anti-blocking agents can be very suitable for IAP processing. It was observed that specific anti-blocking agents can to a high extent decrease the release force of a superstrate after curing the photocurable composition, while maintaining a low contact angle of the photocurable composition. Furthermore, by using high amounts of multi-functional aromatic vinyl monomers, polymeric layers can be formed which are suitable for downstream processing at high temperatures, such as at 350° C., or at 400° C., or even at 450° C., with a high etch resistance.

### EXAMPLES

The following non-limiting examples illustrate the concepts as described herein.

### Example 1

### Preparing of Photocurable Compositions

Two groups of photocurable compositions (group A and group B) were prepared, wherein the photocurable compositions of each group contained as polymerizable material 100% of a multi-functional aromatic vinyl monomer and varying types of anti-blocking agents. Each photocurable composition further contained two photoinitiators.

Specifically, the photocurable compositions of group A contained the following ingredients: 3,3′-divinylbiphenyl (DVBPH), varying types of anti-blocking agent, and the photoinitiators Irgacure 819 (a photoinitiator from IGM Resins) and OXE02 (an oxime ester initiator from BASF).

The photocurable compositions of group B contained 3,5,3′-trivinyldiphenylmethane (TVPM), varying types of anti-blocking agent, and the photoinitiators Irgacure 651 (a photoinitiator from IGM Resins) and Omnirad 1316 (an oxime ester photoinitiator from IGM Resins USA).

A general summary of the compositions of groups A and B is shown in Table 1, and a list of the tested anti-blocking agents (A1 to A14) is provided in Table 2.

TABLE 1

| | Group A | Group B |
|---|---|---|
| DVBPH | 100 | |
| TVPM | | 100 |
| Anti-blocking agent | 1-3 | 1-3 |
| Irgacure 819 | 3 | |
| OXE02 | 3 | |
| Irgacure 651 | | 4 |
| Oxime Ester 1316 | | 1.5 |

TABLE 2
Anti-blocking agents

| Anti-blocking agent | | Mw | Visc. | ST | m | n | o |
|---|---|---|---|---|---|---|---|
| (ABA) | | [g/mol] | [mPa·s] | [mN/m] | (EO) | (PO) | (CH₂) |
| A1 - BLAUNON SA3070 | 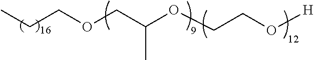 | 2000 | 228 | 32.1 | 12 | 9 | 16 |
| A2 - Brij* S10 | 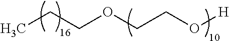 | 711 | 51 | — | 20 | — | 16 |
| A3 - Tergitol 15-S-9 | 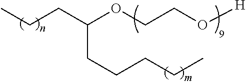 | 596 | 74 | 30.5 | 9 | — | n? |
| A4 - Tergitol NP-9 | 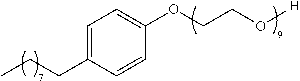 | 616 | 293 | 31.2 | 9 | — | 7 |
| A5 - Tergitol NP-10 | 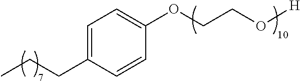 | 682 | 303 | 31.3 | 10 | — | 7 |
| A6 - Lansurf AE310W | 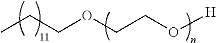 | 640 | 286 | 31 | 10 | — | 11 |
| A7 - Capstone™ FS-3100 | 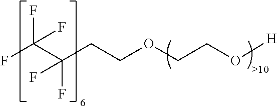 | >750 | 111 | 13 | >10 | — | |
| A8 -WONDERSURF 140 | 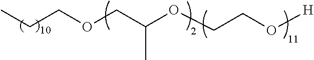 | 750 | 121 | 31 | 11 | 2 | 10 |
| A9 -WONDERSURF NDR1400 | 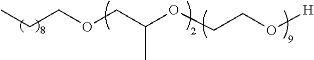 | 650 | 95 | 32 | 9 | 2 | 8 |
| A10 -WONDERSURF S1000 | 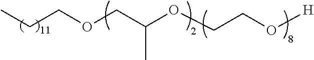 | 650 | 116 | 31 | 8 | 2 | 11 |
| A11 - BLAUNON SA5050 | 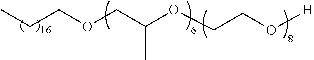 | 1000 | 115 | 32 | 8 | 6 | 16 |
| A12 - ECOSURF™ EH-9 | 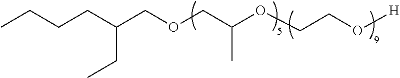 | 799 | 101 | 31 | 9 | 5 | |
| A13 - ECOSURF™ EH-3 | 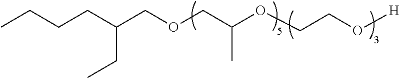 | 535 | 22 | 30 | 3 | 5 | |
| A14 - YK2011 | 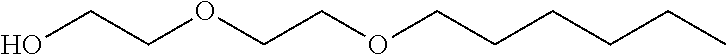 | 234 | 11 | 31 | 2 | — | 3 |

### Example 2

The photocurable compositions described in Example 1 (also called herein IAP resists) were tested to evaluate which anti-blocking agents can efficiently lower the release force of a superstrate (simulated with glass slide) after curing the photocurable composition. A low release force, which corresponds to a low separation energy, is desired, which can reduce imprint defects.

For the testing, the photocurable composition (resist) was dropped onto a glass slide and a further glass slide was placed on top of the resist drops to spread the resist uniformly to a single layer. The resist was photo-cured with UV light by applying a total radiation dosage of 5 J for the photocurable compositions of group A, and 10 J for the photocurable compositions of group B, using a Dymax system. The release force was determined by conducting a 4-point bending test according to a modified ASTM6272, using an Instron 542 instrument.

Comparative experiments were conducted with photocurable compositions (samples C1 and C2) which did not contain an anti-blocking agent, but were otherwise the same as the compositions of group A and B. The measured release force for comparative composition C1 was 1.23 lb, and the release force required for comparative composition C2 was 1.46 lb.

The test results for the photocurable compositions of group A are shown in Table 3, and the results for the compositions falling under group B are shown in Table 4. The actually measured release force was converted to a percentage of the release force reduction, using as comparison the release force required for the comparative composition (C1 or C2, respectively), which did not include an anti-blocking agent.

It can be seen that adding the anti-blocking agents listed in Table 2 to the tested photocurable compositions could reduce the release force needed for the separation of the simulated superstrate. It was surprising that certain anti-blocking agents, such as anti-blocking agents A1 to A6 (which fall under structures of formula 1 and formula 2 herein) could cause a release force reduction by 50% or greater in comparison to the respective photocurable compositions not including an anti-blocking agent. A further advantage of photocurable compositions containing anti-blocking agents A1 to A6 was that the contact angle to a silicon substrate could stay low, often not exceeding 20 degrees, or not even exceeding 15 degrees.

TABLE 3
Varying anti-blocking agents and amounts (Group A compositions)

| | | | | Reduced | |
|---|---|---|---|---|---|
| | Anti- | Amount of anti- | Release | release | |
| | blocking | blocking agent | force | force | CA on |
| Sample | agent | [wt %] | [lb] | [%] | substrate |
| S1 | A3 | 3 | 0.61 | 57.92 | 9 |
| S2 | A4 | 1 | 0.65 | 55.29 | 13 |
| S3 | A1 | 1 | 0.72 | 50.53 | 16 |
| S4 | A3 | 1 | 0.75 | 48.28 | 10 |
| S5 | A12 | 2 | 0.85 | 42.07 | 9 |
| S6 | A12 | 1 | 0.93 | 36.49 | 10 |
| C1 | — | 0 | 1.46 | control | 8 |

TABLE 4
Varying anti-blocking agents and amounts (Group B compositions)

| | | | | Reduced | |
|---|---|---|---|---|---|
| | Anti- | Amount of anti- | Release | release | CA on |
| | blocking | blocking agent | force | force | substrate |
| Sample | agent | [wt %] | [lbs] | [%] | [°] |
| S8 | A1 | 3 | 0.41 | 66.90 | 10.27 |
| S9 | A2 | 3 | 0.58 | 53.31 | 12.20 |
| S10 | A1 | 2 | 0.60 | 51.03 | 13.71 |
| S11 | A2 | 2 | 0.58 | 53.31 | 10.00 |
| S12 | A3 | 2 | 0.58 | 53.08 | 11.40 |
| S13 | A4 | 2 | 0.58 | 52.77 | 10.40 |
| S14 | A5 | 2 | 0.61 | 50.31 | 16.00 |
| S15 | A6 | 1 | 0.60 | 51.57 | 10.49 |
| S16 | A8 | 3 | 0.73 | 40.61 | 16.48 |
| S17 | A12 | 3 | 0.62 | 49.30 | 20.89 |
| S18 | A8 | 2 | 1.04 | 15.46 | 15.07 |
| S19 | A12 | 2 | 0.67 | 45.31 | 20.18 |
| S20 | A9 | 2 | 0.68 | 44.51 | 15.43 |
| S21 | A10 | 2 | 0.68 | 45.12 | 17.13 |
| S22 | A1 | 2 | 0.73 | 40.43 | 13.63 |
| S23 | A13 | 2 | 0.64 | 47.99 | 14.8 |
| S24 | A14 | 2 | 0.65 | 47.38 | 20.9 |
| S25 | A1 | 1 | 0.67 | 45.33 | 9.94 |
| S26 | A3 | 1 | 0.66 | 46.02 | 10.22 |
| S27 | A7 | 1 | 0.49 | 59.95 | 51.00 |
| C2 | — | — | 1.23 | Control | 11.20 |

It can be further seen from Tables 3 and 4 that the reduction of the release force is dependent from the concentration of the anti-blocking agent, and that not all tested anti-blocking agents (regardless of the concentration) achieved a reduction of the release force of at least 50 percent.

Furthermore, while some anti-blocking agents caused a high reduction of the release force, this was not necessarily paired with a low contact angle of the photocurable composition. For example, composition S27, which contained anti-blocking agent A7 (CapstoneTM FS-3100), caused a reduction of the release force by 59.95 percent, however, it also caused an unwanted large increase of the contact angle to 51.00 degrees, while the resist without A7 had a contact angle to silicon substrate of 11.20 degrees. A low contact angle of not greater than 25 degrees is, however, desirable for the photocurable compositions of the present disclosure in order to promote easy resist drop spreading on the substrate and to good wettability of the superstrate.

### Viscosities

The viscosities of the photocurable compositions were measured using a Brookfield Viscometer LVDV-II+Pro at 200 rpm, with a spindle size #18 and a spin speed of 135 rpm. For the viscosity testing, about 6-7 mL of sample liquid was added into the sample chamber, enough to cover the spindle head. The sample contained in the chamber was about 20 minutes equilibrated to reach the desired measuring temperature of 23° C. before the actual measurement was started. For all viscosity testing, at least three measurements were conducted and an average value was calculated.

The measured viscosities ranged from 18 mPa·s to 27 mPa·s.

### Surface Tension Measurement

The surface tension of the anti-blocking agents was measure by the Pendant Drop method using a DM-701 contact angle meter made by Kyowa Interface Science Co. Ltd (Japan). For the measurement, a syringe containing the anti-blocking agent to be tested was loaded on the syringe holder, and a measuring program of the Pendant Drop control panel was started. The SM-701 allows automatic liquid dispensing and drop size control. The drop images were captured and the drop shapes were analyzed with the help of a software program using the Young-Laplace theory to obtain the surface tension.

### Contact Angle to Silicon Substrate

The contact angle of the photocurable compositions to the surface of a silicon wafer (substrate) was measured using a Drop master DM-701 contact angle meter (made by Kyowa Interface Science Co. Ltd., Japan). For each contact angle measurement, a drop of 2 μl of the test composition was added by the machine to the target surface. Drop images were continuously captured by a CCD camera from the time the water drop touched the target surface. The contact angle was automatically calculated by software associated with the Drop master DM-701 contact angle meter. The data shown in tables 3 and 4 correspond to the contact angle at a time of 3 seconds after touching the target surface.

### Dynamic Thermogravimetry

The thermal stability of the photo-cured layers was investigated via dynamic thermal gravimetric analysis (TGA) using a LINSEIS STA PT1000 instrument (Linseis Messgeraete GmbH, Germany). All measurements were conducted under nitrogen at a rate of 5 liter per hour.

For the TGA measurements, 25-35 mg of the photo-cured sample was placed in a crucible and the initial weight recorded. A reference crucible was used to monitor the weight change of the crucible due to the variation of the temperature. The sample was heated at a rate of 20° C./min and the weight loss of the sample with increasing temperature was recorded at intervals of 1 second. The relative weight percent change was calculated by using the weight loss divided by the total original weight of the sample.

The initial degradation temperature T(X) for each curve was identified by determining the point of deflection from an established baseline of the TGA curve. The measured degradation temperature (T(X) for representative samples S1 was 375° C., and for sample S8 was and 419° C.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any sub combination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A photocurable composition comprising a polymerizable material, an anti-blocking agent, and a photoinitiator, wherein
the polymerizable material consists essentially of at least one multi-functional aromatic vinyl monomer;
the anti-blocking agent has a structure of formula (1) or formula (2): 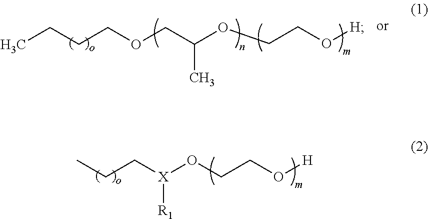
wherein m is 8-15, n is 7-15, o is 8-20; X is aryl or CH₂, and R₁ is H or C₁-C₁₀-alkyl; and
a viscosity of the photocurable composition is not greater than 50 mPa·s at 23° C.

2. The photocurable composition of claim 1, wherein an amount of the anti-blocking agent is at least 0.2 wt % and not greater than 5 wt % based on the total weight of the photocurable composition.

3. The photocurable composition of claim 1, wherein the anti-blocking agent has the structure of formula (1): 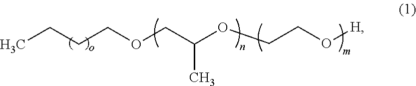
wherein m is 9-15, n is 7-12, and o is 13-20.

4. The photocurable composition of claim 1, wherein the at least one multi-functional aromatic vinyl monomer includes a divinylbiphenyl monomer (DVBPh), or a trivinylbiphenyl monomer (TVBPh), or a trivinylphenyl monomer (TVPh), or a combination thereof.

5. The photocurable composition of claim 1, wherein the multi-functional aromatic vinyl monomer is selected from: 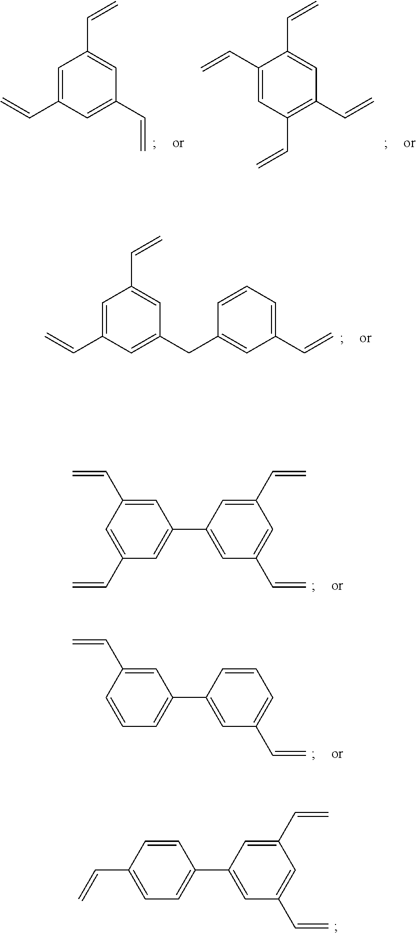
or any combination thereof.

6. The photocurable composition of claim 5, wherein the multi-functional aromatic vinyl monomer includes 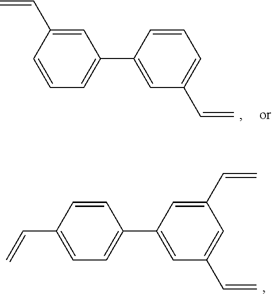
or a combination thereof.

7. The photocurable composition of claim 1, wherein an amount of the polymerizable material is at least 90 wt % based on the total weight of the photocurable composition.

8. The photocurable composition of claim 1, wherein a carbon content of the polymerizable material is at least 90 percent based on the total weight of the polymerizable material.

9. The photocurable composition of claim 1, wherein the photocurable composition is essentially free of a solvent.

10. The photocurable composition of claim 1, wherein the photocurable composition is essentially free of a fluorine-containing surfactant.

11. The photocurable composition of claim 1, wherein the anti-blocking agent comprises a surface tension of at least 28 mN/m and not greater than 37 mN/m.

12. The photocurable composition of claim 1, wherein a contact angle of the photocurable composition towards a surface of a silicon substrate is not greater than 25°.

13. The photocurable composition of claim 1, wherein a release force reduction of the photocurable composition is at least 50%.

14. A laminate comprising a substrate and a photo-cured layer overlying the substrate, wherein the photo-cured layer is formed from the photocurable composition of claim 1.

15. The laminate of claim 14, wherein the photo-cured layer has an initial degradation temperature T(X) of at least 350° C.

16. A method of forming a photo-cured layer on a substrate, comprising:
applying a layer of a photocurable composition on the substrate, wherein the photocurable composition comprises a polymerizable material, an anti-blocking agent, and a photoinitiator, wherein the polymerizable material consists essentially of at least one multi-functional aromatic vinyl monomer; the anti-blocking agent has a structure of formula (1) or formula (2): 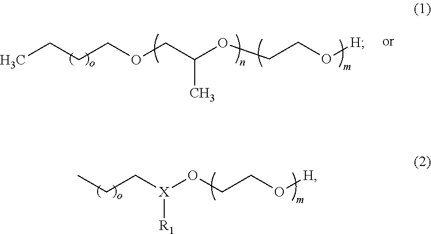
wherein m is 8-15, n is 7-15, and o is 8-20; X is aryl or CH₂, and R₁ is H or C₁-C₁₀-alkyl, and a viscosity of the photocurable composition is not greater than 50 mPa s at 23° C.;
bringing the photocurable composition into contact with a superstrate or an imprint template;
irradiating the photocurable composition with light to form a photo-cured layer; and
removing the superstrate or the imprint template from the photo-cured layer.

17. The method of claim 16, wherein a release force reduction of the photocurable composition is at least 50%.

18. The method of claim 16, wherein the at least one multi-functional aromatic vinyl monomer includes a divinylbiphenyl monomer (DVBPh), or a trivinylbiphenyl monomer (TVBPh), or a trivinylphenyl monomer (TVPh), or a combination thereof.

19. The method of claim 16, wherein an initial degradation temperature T(X) of the photo-cured layer is at least 350° C.

20. A method of manufacturing an article, comprising:
applying a layer of a photocurable composition on a substrate, wherein the photocurable composition comprises a polymerizable material, an anti-blocking agent, and a photoinitiator, wherein the polymerizable material consists essentially of at least one multi-functional aromatic vinyl monomer; the anti-blocking agent has a structure of formula (1) or formula (2): 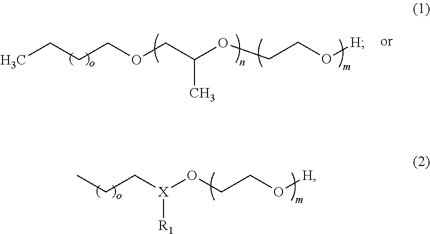
wherein m is 8-15, n is 7-15, and o is 8-20; X is benzol or CH₂, and R₁ is H or C₁-C₁₀-alkyl, and a viscosity of the photocurable composition is not greater than 50 mPa s at 23° C.;
bringing the photocurable composition into contact with a template or a superstrate;
irradiating the photocurable composition with light to form a photo-cured layer;
removing the template or the superstrate from the photo-cured layer;
forming a pattern on the substrate;
processing the substrate on which the pattern has been formed in the forming; and
manufacturing an article from the substrate processed in the processing.
